(19) United States
(12) Patent Application Publication
(10) Pub. No.: US 2008/0121909 A1
(43) Pub. Date: May 29, 2008

(54) Semiconductor device

(75) Inventors: Minoru Niigaki, Hamamatsu-shi (JP); Toru Hirohata, Hamamatsu-shi (JP); Kazutoshi Nakajima, Hamamatsu-shi (JP); Hirofumi Kan, Hamamatsu-shi (JP)

Correspondence Address: DRINKER BIDDLE & REATH (DC), 1500 K STREET, N.W., SUITE 1100, WASHINGTON, DC, 20005-1209, US

(73) Assignee: HAMAMATSU PHOTONICS K.K.

(21) Appl. No.: 11/987,215

(22) Filed: Nov. 28, 2007

(30) Foreign Application Priority Data
Nov. 29, 2006 (JP) P2006-322340

(51) Int. Cl. H01L 33/00; H01L 31/0336

(52) U.S. Cl. 257/94; 257/184; 257/E31.005; 257/E33.024

(57) ABSTRACT

A semiconductor device has first and second III-V compound semiconductor layers one of which functions as a photosensitive layer or as a light emitting layer, which are doped with a p-type impurity in a low concentration, and which are joined to each other to make a heterojunction. An energy gap of the second III-V compound semiconductor layer is smaller than that of the first III-V compound semiconductor layer and the p-type dopant in each semiconductor layer is Be or C. At this time, the second III-V compound semiconductor layer may be deposited on the first III-V compound semiconductor layer. The first III-V compound semiconductor layer and the second III-V compound semiconductor layer may contain at least one from each group of (In, Ga, Al) and (As, P, N).

### BACKGROUND OF THE INVENTION

1. Field of the Invention

The present invention relates to a semiconductor device.

2. Related Background Art

Conventionally, for example, zinc (Zn) is used as a p-type dopant in growth of thin films of III-V compound semiconductors. At this time, there arises a problem that abnormal diffusion of Zn as the p-type impurity occurs when the concentration of the p-type impurity is, for example, as high as about 1×10²⁰ cm⁻³ or more.

Patent Documents 1-5 point out this problem and describe that the problem is solved by using beryllium (Be) or carbon (C) as the p-type dopant.

### [Patent document 1] Japanese Patent No. 3224057

### [Patent document 2] Japanese Patent No. 2646966

### [Patent document 3] Japanese Patent No. 2761264

[Patent document 4] Japanese Patent Application Laid-open No. H5-136397

### [Patent document 5] Japanese Patent Application Laid-open No. 2001-36195

### DISCLOSURE OF THE INVENTION

### Problem to be Solved by the Invention

Incidentally, the abnormal diffusion of the p-type impurity could occur in growth of a III-V compound semiconductor even in cases where the concentration of the p-type impurity is, for example, as low as about 1×10⁸ cm⁻³ or less, different from the situation noted in Patent Documents 1-5 above. When the abnormal diffusion of the p-type impurity occurs in such a low concentration region, it becomes infeasible to accurately control the carrier concentration in the p-type compound semiconductor layer and, as a result, there arises a problem that a semiconductor device, an optical device, or the like including the p-type compound semiconductor layer fails to hold characteristics as expected.

Therefore, the present invention has been accomplished in view of the above-described circumstances and an object of the invention is to provide a semiconductor device capable of preventing the abnormal diffusion of the p-type impurity in the low concentration region.

### SUMMARY OF THE INVENTION

### Means for Solving the Problem

The inventor conducted elaborate research and found out the fact as described below. Namely, the inventor discovered the following fact: “In a semiconductor device using Zn as a p-type dopant and having a heterostructure, where a semiconductor layer of a p-type binary compound semiconductor (which will also be referred to as a “binary semiconductor layer”) doped with Zn in the low concentration of not more than 1×10¹⁸ cm⁻³ is deposited on a III-V compound semiconductor layer of a p-type ternary compound semiconductor or a III-V compound semiconductor layer of a p-type quaternary compound semiconductor (which will also be referred to as a “ternary/quaternary semiconductor layer”) doped with Zn in the low concentration of not more than 11×10¹⁸ cm³, the predetermined Zn doping concentration as designed is achieved as proved by analysis of concentration distribution after deposition. However, when the ternary/quaternary semiconductor layer is deposited on the binary semiconductor layer contrary to the above, the abnormal diffusion of Zn occurs in the binary semiconductor layer as proved by analysis of concentration distribution after deposition and the predetermined Zn doping concentration as designed is not achieved in the binary semiconductor layer.”

The inventor conducted further elaborate research and further discovered the following fact: “When a semiconductor device is formed in a configuration wherein it has a first III-V compound semiconductor layer and a second III-V compound semiconductor layer making a heterojunction and wherein the energy gap of the second III-V compound semiconductor layer is smaller than that of the first III-V compound semiconductor layer, the abnormal diffusion of the p-type impurity does not occur from a growth system or growth conditions, but occurs from the essential problems arising from the semiconductor heterostructure and the type of the p-type impurity.” There are no prior art documents pointing out this problem of abnormal diffusion (e.g., none of the prior patent documents including Patent Documents 1-5 above describes it) and no reason for it has been elucidated. The present invention has been accomplished on the basis of the new findings as described above and in order to prevent the abnormal diffusion of the p-type impurity in the low concentration region in the case where the ternary/quaternary semiconductor layer is deposited on the binary semiconductor layer.

Specifically, a semiconductor device of the present invention comprises a first III-V compound semiconductor layer and a second III-V compound semiconductor layer one of which functions as a photosensitive layer or as a light emitting layer, which are doped with a p-type impurity, and which are joined to each other to make a heterojunction. An energy gap of the second III-V compound semiconductor layer is smaller than an energy gap of the first III-V compound semiconductor layer and Be or C is used as the p-type dopant in each of the III-V compound semiconductor layers. In this case, the second III-V compound semiconductor layer may be deposited on the first III-V compound semiconductor layer. The first III-V compound semiconductor layer and the second III-V compound semiconductor layer may contain at least one from each group of (In, Ga, Al) and (As, P, N). At this time, preferably, the first III-V compound semiconductor layer is a III-V compound semiconductor layer of a binary compound semiconductor and the second III-V compound semiconductor layer is a III-V compound semiconductor layer of a ternary compound semiconductor or a quaternary compound semiconductor. The first III-V compound semiconductor layer and the second III-V compound semiconductor layer may be grown by molecular beam epitaxy (MBE). The first III-V compound semiconductor layer and the second III-V compound semiconductor layer may be doped with the p-type impurity in a low concentration of not more than 1×10¹⁸ cm⁻³.

Since the semiconductor device of the present invention as described above uses Be or C, which has the diffusion coefficient smaller than that of Zn, i.e., which has the atomic radius smaller than that of Zn, as the p-type dopant in the first III-V compound semiconductor layer and the second III-V compound semiconductor layer, it is able to prevent the abnormal diffusion of the p-type dopant in the first III-V compound semiconductor layer.

### Effect of the Invention

The present invention enables the prevention of the abnormal diffusion of the p-type impurity in the low concentration region. This permits us to accurately control the carrier concentration in the deposited semiconductor layer, so that the semiconductor device, an optical device, or the like fabricated with the semiconductor layer can hold characteristics as expected.

### BRIEF DESCRIPTION OF THE DRAWINGS

FIG. 1 is a sectional view showing a layer structure of a semiconductor device according to an embodiment of the present invention.

FIG. 2 is a drawing showing a table of designed particulars about the semiconductor device of the embodiment.

FIG. 3 is a drawing showing the result of measurement of concentration distribution of Be atoms by SIMS, with the semiconductor device of the embodiment.

FIG. 4 is a schematic sectional view showing a surface emitting diode including a semiconductor device.

FIG. 5 is a schematic sectional view showing a back-illuminated type photodiode including a semiconductor device.

FIG. 6 is a drawing showing a table of designed particulars about a first prototype device.

FIG. 7 is a drawing showing the result of measurement of concentration distribution of Zn atoms by SIMS, with the first prototype device.

FIG. 8 is a drawing showing a table of designed particulars about a second prototype device.

FIG. 9 is a drawing showing the result of measurement of concentration distribution of Zn atoms by SIMS, with the second prototype device.

FIG. 10 is a drawing showing a table of designed particulars about a third prototype device.

### DESCRIPTION OF REFERENCE SYMBOLS

100 semiconductor device; 102 n-type InP substrate; 104 n-type InP semiconductor layer (first layer); 106 n-type InGaAsP semiconductor layer (second layer); 108 n-type InP semiconductor layer (third layer); 110 p-type InP semiconductor layer (fourth layer); 112 p-type InGaAsP semiconductor layer (fifth layer); 114 p-type InP semiconductor layer (sixth layer); 200 surface emitting diode; 202, 218 electrodes; 204 n-type InP substrate; 206 n-type InGaAsP etching stop layer; 208 n-type InP cladding layer; 210 p-type InP joining layer; 212 p-type InGaAsP active layer; 214 p-type InP cladding layer; 216 SiO₂ insulating layer; 220 heat sink for heat radiation; 300 back-illuminated type photodiode; 302, 316 electrodes; 304 SiO₂ insulating layer; 306 p-type InP cladding layer; 308 p-type InGaAsP active layer; 310 p-type InP joining layer; 312 n-type InP cladding layer; 314 n-type InP substrate.

### DESCRIPTION OF THE PREFERRED EMBODIMENTS

### Best Mode for Carrying out the Invention

Preferred embodiments of the semiconductor device according to the present invention will be described below in detail with reference to the accompanying drawings. The same elements will be denoted by the same reference symbols throughout the description of the drawings, without redundant description. It is also noted that dimensional ratios in the drawings do not always agree with those in the description.

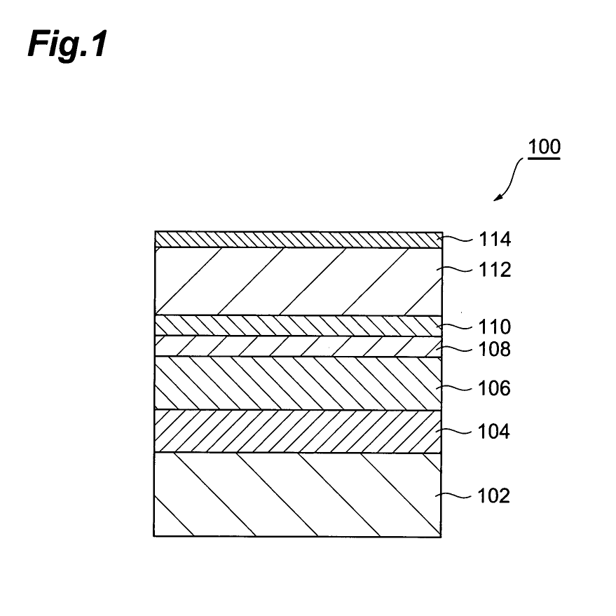

FIG. 1 is a sectional view showing a layer structure of a semiconductor device 100 according to an embodiment of the present invention. As shown in FIG. 1, the semiconductor device 100 has the structure in which the following layers are stacked in the order named, on an n-type InP substrate 102: n-type InP semiconductor layer 104 (first layer); n-type InGaAsP semiconductor layer 106 (second layer); n-type InP semiconductor layer 108 (third layer); p-type InP semiconductor layer 110 (fourth layer, which is the first III-V compound semiconductor layer of the p-type binary compound semiconductor); p-type InGaAsP semiconductor layer 112 (fifth layer, which is the second III-V compound semiconductor layer of the p-type ternary compound semiconductor or the p-type quaternary compound semiconductor); and p-type InP semiconductor layer 114 (sixth layer).

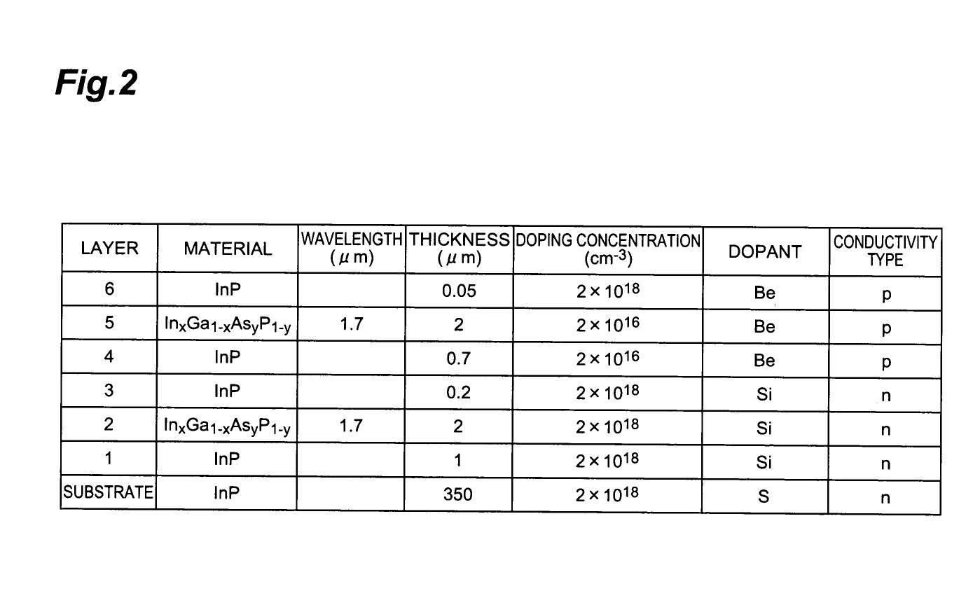

FIG. 2 is a drawing showing a table of the designed particulars of the materials, thicknesses, etc. of the respective layers, as an example for fabrication of the semiconductor device 100. In the semiconductor device 100, as shown in FIG. 2, the InP substrate 102 is so designed that its thickness is 350 μm and that the doping concentration of sulfur (S) is 2×10¹⁸ cm⁻³. The n-type InP semiconductor layer 104 of the first layer is so designed that its thickness is 1 μm and that the doping concentration of Si is 2×10¹⁸ cm⁻³. The n-type InGaAsP semiconductor layer 106 of the second layer is so designed that its wavelength corresponding to the energy gap at room temperature is 1.7 μm, that its thickness is 2 μm, and that the doping concentration of Si is 2×10¹⁸ cm⁻³. The n-type InP semiconductor layer 108 of the third layer is so designed that its thickness is 0.2 μm and that the doping concentration of Si is 2×10¹⁸ cm⁻³.

The p-type InP semiconductor layer 110 of the fourth layer is so designed that its thickness is 0.7 μm and that the doping concentration of Be is 2×10¹⁶ cm³. The p-type InGaAsP semiconductor layer 112 of the fifth layer is so designed that its wavelength is 1.7 μm, that the thickness is 2 μm, and that the doping concentration of Be is 2×10¹⁶ cm⁻³. The energy gap of this fifth layer is designed to be smaller than that of the fourth layer. The p-type InP semiconductor layer 114 of the sixth layer is so designed that its thickness is 0.05 μm and that the doping concentration of Be is 2×10¹⁸ cm⁻³.

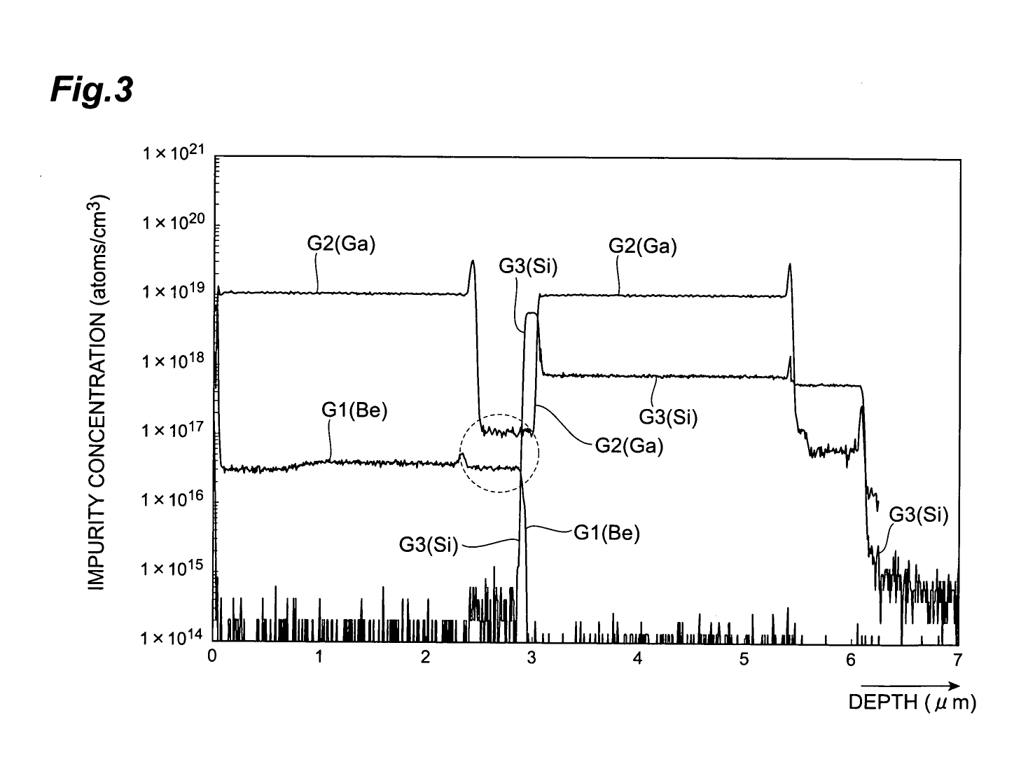

Each of the layers was epitaxially grown in order based on the above-described design by MBE to fabricate the semiconductor device 100 of the present embodiment as shown in FIG. 1. FIG. 3 is a drawing showing the result of measurement to measure the concentration distribution of Be atoms as the p-type dopant by secondary ion mass spectroscopy (which will be referred to hereinafter as “SIMS”), with the fabricated semiconductor device 100. FIG. 3 shows the concentration distribution of Be atoms in the depth direction from the sixth layer side of the top layer to the substrate side of the bottom layer in the semiconductor device 100. Namely, the upper surface of the sixth layer in the semiconductor device 100 has the depth equivalent to “0 μm” in FIG. 3. In FIG. 3, the concentration distribution of Be atoms is indicated by graph G1. In order to identify the interfaces between the layers, the concentration distribution of Ga atoms is indicated by graph G2 and the concentration distribution of Si atoms by graph G3.

As shown in FIG. 3, the measured doping concentrations of Be in the respective layers agree with the doping concentrations of Be (in the fifth column in FIG. 2) according to the design as shown in FIG. 2. Particularly, noting the part of the p-type InP layer of the fourth layer encircled by a dotted line in FIG. 3, it can be confirmed that the atomic concentration of Be is the predetermined value of 2×10¹⁶ cm⁻³ as designed.

The above result shown in FIG. 3 is also achieved in the following cases, as well as in the above-described case where the fourth layer is the p-type InP semiconductor layer and where the fifth layer is the p-type InGaAsP semiconductor layer. Namely, the result similar to the result shown in FIG. 3 is achieved in cases where the fourth layer and the fifth layer contain at least one from each group of (In, Ga, Al) and (As, P, N) and where the energy gap of the fourth layer is larger than that of the fifth layer. In addition, the result similar to the result shown in FIG. 3 is also achieved in cases where the fourth layer is a semiconductor layer of a binary compound semiconductor and where the fifth layer is a semiconductor layer of a ternary compound semiconductor. Furthermore, the result similar to the result shown in FIG. 3 is also achieved in cases where C is used as the p-type dopant, as well as in the cases where Be is used as the p-type dopant.

In the semiconductor device 100 of the present embodiment as described above, Be or C having the diffusion coefficient smaller than that of Zn, i.e., having the atomic radius smaller than that of Zn is used as the p-type dopant in the fourth layer and the fifth layer, which can prevent the abnormal diffusion of the p-type dopant in the fourth layer.

In the present embodiment, each of the layers constituting the semiconductor device 100 is epitaxially grown by MBE. The reason for it is that the MBE process is a preferred epitaxial growth method using Be as the p-type dopant.

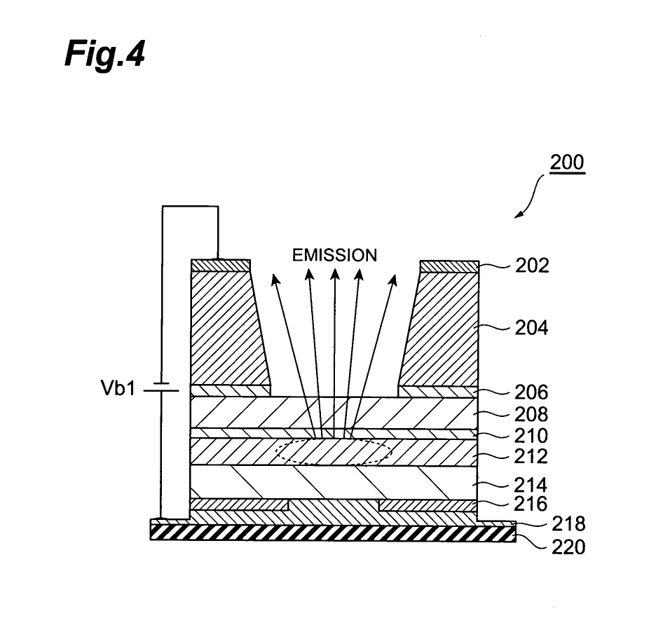

The semiconductor device of the present invention described above using the semiconductor device 100 of the present embodiment as an example can be used as an optical device such as a semiconductor light emitting device or a semiconductor light receiving device. FIG. 4 is a schematic sectional view schematically showing a surface emitting diode 200 as an example of the optical device.

As shown in FIG. 4, the surface emitting diode 200 has electrodes 202, 218, an n-type InP substrate 204, an n-type InGaAsP etching stop layer 206, an n-type InP cladding layer 208, a p-type InP joining layer 210, a p-type InGaAsP active layer 212, a p-type InP cladding layer 214, a SiO₂ insulating layer 216, and a heat sink 220 for heat radiation.

For fabricating the surface emitting diode 200, the Si-doped n-type InGaAsP etching stop layer 206, Si-doped n-type InP cladding layer 208, Be-doped p-type InP joining layer 210 (the first III-V compound semiconductor layer of the p-type binary compound semiconductor), Be-doped p-type InGaAsP active layer 212 (the second III-V compound semiconductor layer of the p-type ternary compound semiconductor or the p-type quaternary compound semiconductor), and Be-doped p-type InP cladding layer 214 are first epitaxially grown in order on the S-doped n-type InP substrate 204 by MBE. Thereafter, the SiO₂ insulating layer 216 is deposited on the Be-doped p-type InP cladding layer 214, for example, by plasma CVD.

Next, a part of the SiO₂ insulating layer 216 is removed, for example, by photolithography and etching, and the electrode 218 is then evaporated. Then the electrode 202 is evaporated on the S-doped n-type InP substrate 204. A part of the electrode 202 and the S-doped n-type InP substrate 204 is removed, for example, by photolithography and etching. At this time, an appropriate etching solution is selected so that the etching can stop automatically at the Si-doped n-type InGaAsP etching stop layer 206. Furthermore, another appropriate etching solution is selected to etch the Si-doped n-type InGaAsP etching stop layer 206. Finally, the resultant layer structure is mounted up side down on the heat sink 220 for heat radiation, thereby completing the surface emitting diode 200.

This surface emitting diode 200 operates as a light emitting diode when a forward bias voltage Vb1 is applied between the two electrodes 202, 218. Emission from the Be-doped p-type InGaAsP active layer 212 is extracted upward through the Be-doped p-type InP joining layer 210 and Si-doped n-type InP cladding layer 208, as shown in FIG. 4. At this time, the abnormal diffusion of the p-type dopant, which used to occur in the conventional structure, does not occur in the Be-doped p-type InP joining layer 210, which increases the luminous efficiency significantly.

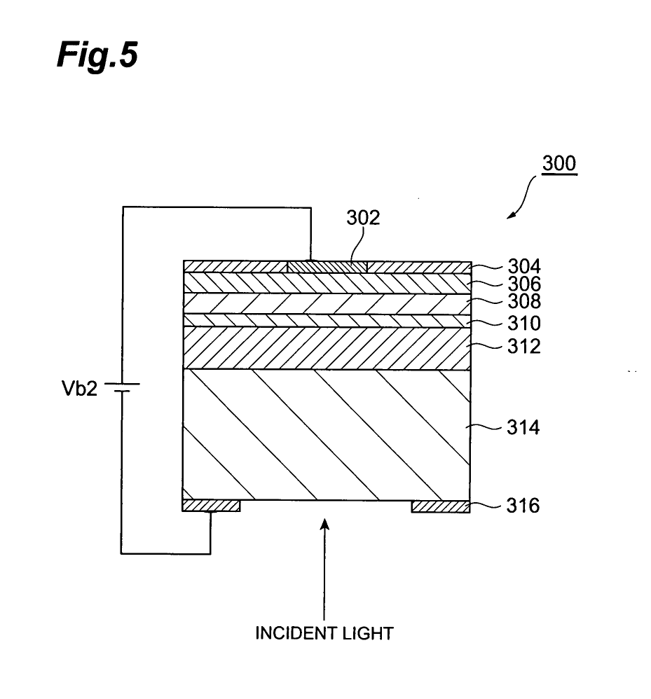

The semiconductor device of the present invention can also be used as a semiconductor light receiving device, without being limited to the semiconductor light emitting device as described above. FIG. 5 is a schematic sectional view schematically showing a back-illuminated type photodiode 300, as an example of the semiconductor light receiving device.

As shown in FIG. 5, the back-illuminated photodiode 300 has electrodes 302, 316, a SiO₂ insulating layer 304, a Be-doped p-type InP cladding layer 306, a Be-doped p-type InGaAsP active layer 308, a Be-doped p-type InP joining layer 310, a Si-doped n-type InP cladding layer 312, and a S-doped n-type InP substrate 314.

For fabricating the back-illuminated photodiode 300, the Si-doped n-type InP cladding layer 312, Be-doped p-type InP joining layer 310 (the first III-V compound semiconductor layer of the p-type binary compound semiconductor), Be-doped p-type InGaAsP active layer 308 (the second III-V compound semiconductor layer of the p-type ternary compound semiconductor or the p-type quaternary compound semiconductor), and Be-doped p-type InP cladding layer 306 are first epitaxially grown in order on the S-doped n-type InP substrate 314 by MBE. Thereafter, the SiO₂ insulating layer 304 is deposited on the Be-doped p-type InP cladding layer 306, for example, by plasma CVD.

Next, a part of the SiO₂ insulating layer 304 is removed, for example, by photolithography and etching, and the electrode 302 is then evaporated. Then the electrode 316 is evaporated on the S-doped n-type InP substrate 314. A part of the electrode 316 is then removed, for example, by photolithography and etching.

This back-illuminated photodiode 300 operates as a photodiode when a backward bias voltage Vb2 is applied between the two electrodes 302, 316. Light to be measured is incident to the S-doped n-type InP substrate 314 side, travels through the S-doped n-type InP substrate 314, Si-doped n-type InP cladding layer 312, and Be-doped p-type InP joining layer 310, and is absorbed in the Be-doped p-type InGaAsP active layer 308 to generate carriers. At this time, the abnormal diffusion of the p-type dopant, which used to occur in the conventional structure, does not occur in the Be-doped p-type InP joining layer 310, which increases acceptance sensitivity drastically and decreases dark current significantly.

The present invention, the examples of which were described above, has been accomplished based on the new findings as described below.

The inventor conducted elaborate research and found out the fact as described below. Namely, the inventor discovered the following fact: “In a semiconductor device using Zn as a p-type dopant and having a heterostructure, where a semiconductor layer of a p-type binary compound semiconductor (binary semiconductor layer, or the first III-V compound semiconductor layer) doped with Zn in the low concentration of not more than 1×10¹⁸ cm⁻³ is deposited on a semiconductor layer of a p-type ternary compound semiconductor or a semiconductor layer of a p-type quaternary compound semiconductor (ternary/quaternary semiconductor layer, or the second III-V compound semiconductor layer) doped with Zn in the low concentration of not more than 1×10¹⁸ cm⁻³, the predetermined Zn doping concentration as designed is achieved as proved by analysis of concentration distribution after deposition. However, when the ternary/quaternary semiconductor layer is deposited on the binary semiconductor layer contrary to the above, the abnormal diffusion of Zn occurs in the binary semiconductor layer as proved by analysis of concentration distribution after deposition and the predetermined Zn doping concentration as designed is not achieved in the binary semiconductor layer.”

The inventor conducted further elaborate research and further discovered the following fact: “When a semiconductor device is formed in a configuration wherein it has a first III-V compound semiconductor layer and a second III-V compound semiconductor layer making a heterojunction and wherein the energy gap of the second III-V compound semiconductor layer is smaller than that of the first III-V compound semiconductor layer, the abnormal diffusion of the p-type impurity does not occur from a growth system or growth conditions, but occurs from the essential problems arising from the semiconductor heterostructure and the type of the p-type impurity.” There are no prior art documents pointing out this problem of abnormal diffusion and no reason for it has been elucidated. The present invention has been accomplished on the basis of the new findings as described above and in order to prevent the abnormal diffusion of the p-type impurity in the low concentration region in the case where the ternary/quaternary semiconductor layer is deposited on the binary semiconductor layer.

The above contents will be described below in more detail. First, the inventor experimentally manufactured a semiconductor device of a heterostructure (which will also be referred to hereinafter as a “first prototype device”) by metal organic vapor phase epitaxy (hereinafter referred to as “MOCVD”). The first prototype device has the structure in which a p-type InP substrate, a p-type InP semiconductor layer (first layer), a p-type InGaAsP semiconductor layer (second layer), a p-type InP semiconductor layer (third layer), and an n-type InP semiconductor layer (fourth layer) are stacked in order.

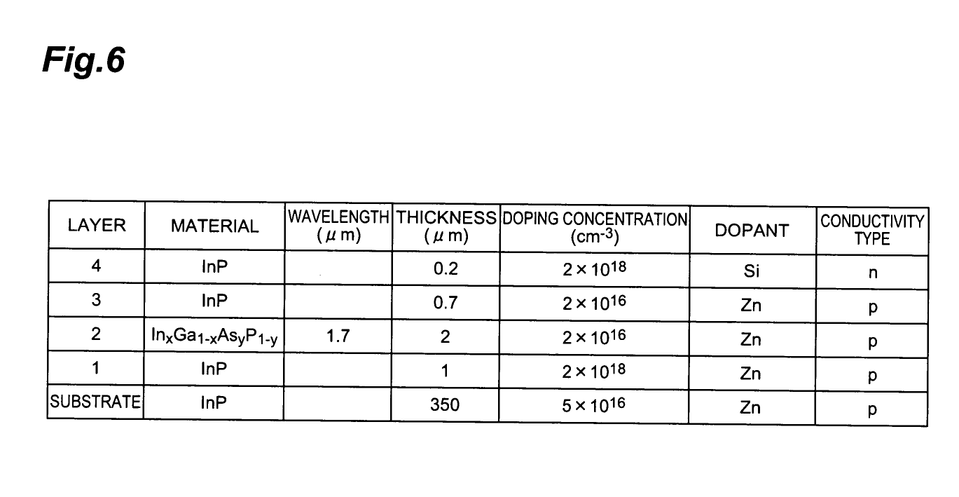

FIG. 6 is a drawing showing a table of the designed particulars of the materials, thicknesses, etc. of the respective layers, for experimentally manufacturing the first prototype device. In the first prototype device with the heterostructure, as shown in FIG. 6, the InP substrate is so designed that its thickness is 350 μm and that the doping concentration of Zn is 5×10¹⁶ cm⁻³. The first layer is so designed that its thickness is 1 μm and that the doping concentration of Zn is 2×10¹⁸ cm⁻³. The second layer is so designed that its wavelength is 1.7 μm, that its thickness is 2 μm, and that the doping concentration of Zn is 2×10¹⁶ cm³. The third layer is so designed that its thickness is 0.7 μm and that the doping concentration of Zn is 2×10¹⁶ cm⁻³. The fourth layer is so designed that its thickness is 0.2 μm and that the doping concentration of silicon (Si) is 2×10¹⁸ cm⁻³.

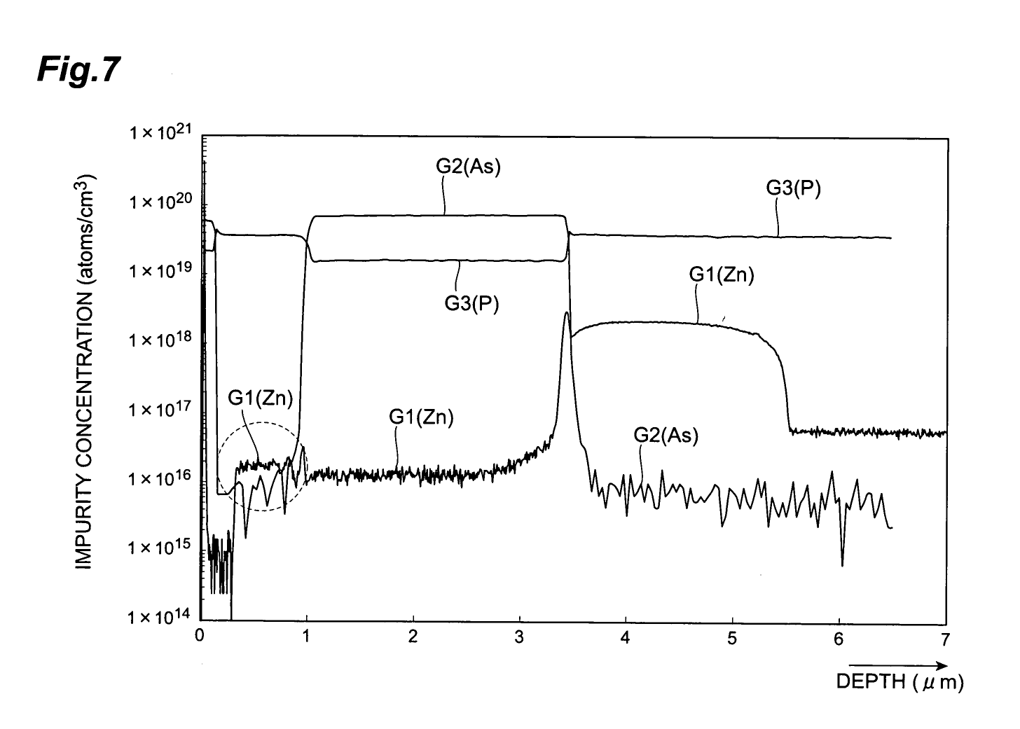

Based on the above design, each of the layers was epitaxially grown in order by MOCVD, thereby experimentally manufacturing the first prototype device. FIG. 7 is a drawing showing the result of measurement to measure the concentration distribution of Zn atoms as the p-type dopant in the first prototype device by SIMS. In FIG. 7 the measurement result is shown in the form similar to that in FIG. 3 described above, wherein the concentration distribution of Zn atoms is indicated by graph G1, the concentration distribution of As atoms by graph G2, and the concentration distribution of P atoms by graph G3. As shown in FIG. 7, the measured doping concentrations of Zn in the respective layers agree with the doping concentrations of Zn (in the fifth column in FIG. 6) according to the design shown in FIG. 6. Particularly, noting the part of the p-type InP layer of the third layer encircled by a dotted line in FIG. 7, it can be confirmed that the atomic concentration of Zn is the predetermined value of 2×10¹⁶ cm⁻³ as designed.

With respect to the first prototype device with the as-designed doping concentrations confirmed as described above, the inventor experimentally manufactured another semiconductor device of a heterostructure (which will also be referred to as a “second prototype device”) in the same manner by MOCVD. The second prototype device has the structure in which an n-type InP substrate, an n-type InP semiconductor layer (first layer), an n-type InGaAsP semiconductor layer (second layer), an n-type InP semiconductor layer (third layer), a p-type InP semiconductor layer (fourth layer), a p-type InGaAsP semiconductor layer (fifth layer), and a p-type InP semiconductor layer (sixth layer) are stacked in order.

Namely, the first prototype device with the heterostructure has the structure in which the p-type InP layer (third layer, or p-type binary semiconductor layer) is deposited on the p-type InGaAsP layer (second layer, or p-type ternary/quaternary semiconductor layer), whereas the second prototype device with the heterostructure as well has the structure in which the p-type InGaAsP layer (fifth layer, or p-type ternary/quaternary semiconductor layer) is deposited on the p-type InP layer (fourth layer, or p-type binary semiconductor layer) on the n-type InP semiconductor layer (third layer).

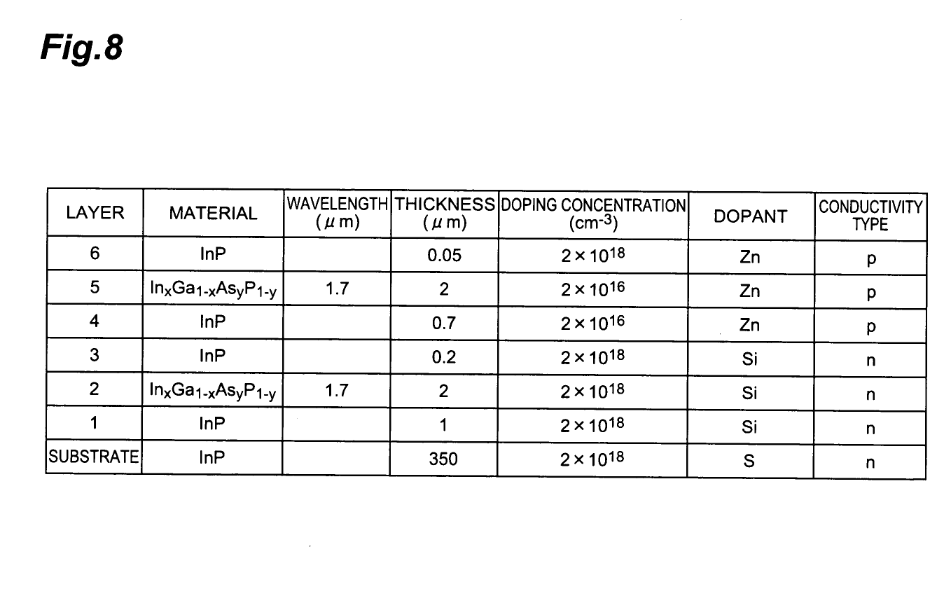

FIG. 8 is a drawing showing a table of the designed particulars of the materials, thicknesses, etc. of the respective layers, for experimentally manufacturing the second prototype device. In the second prototype device with the heterostructure, as shown in FIG. 8, the InP substrate is so designed that its thickness is 350 μm and that the doping concentration of S is 2×10¹⁸ cm⁻³. The first layer is so designed that its thickness is 1 μm and that the doping concentration of Si is 2×10¹⁸ cm⁻³. The second layer is so designed that its wavelength is 1.7 μm, that its thickness is 2 μg/m, and that the doping concentration of Si is 2×10¹⁸ cm⁻³.

The third layer is so designed that its thickness is 0.2 μm and that the doping concentration of Si is 2×10¹⁸ cm⁻³. The fourth layer is so designed that its thickness is 0.7 μm and that the doping concentration of Zn is 2×10¹⁶ cm³. The fifth layer is so designed that its wavelength is 1.7 μm, that its thickness is 2 μm, and that the doping concentration of Zn is 2×10¹⁶ cm⁻³. The sixth layer is so designed that its thickness is 0.05 μm and that the doping concentration of Zn is 2×10¹⁸ cm⁻³.

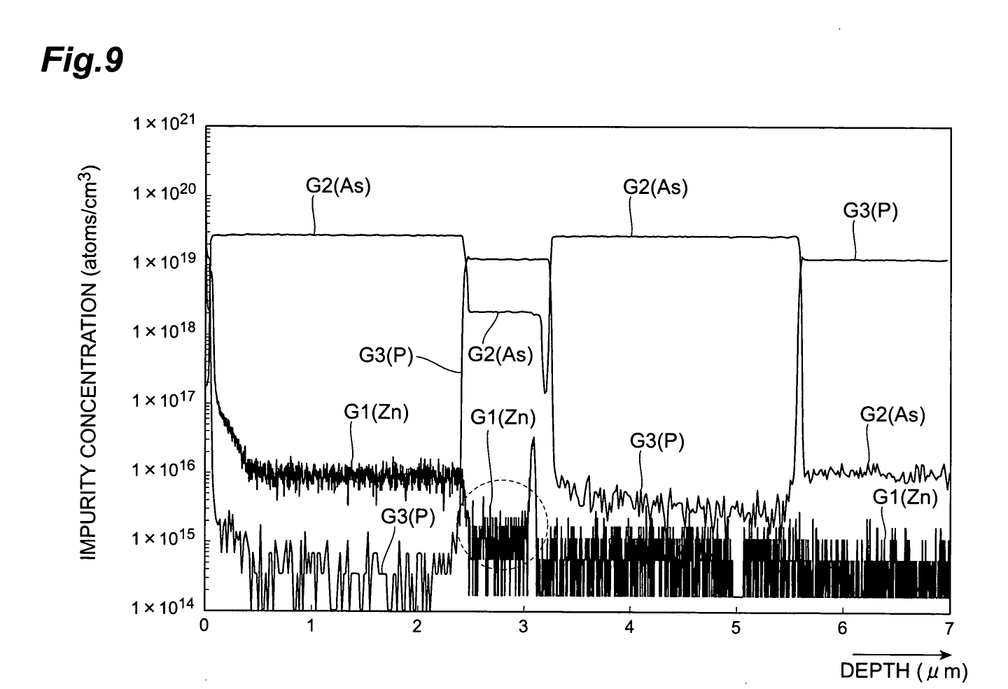

Based on the above design, each of the layers was epitaxially grown in order by MOCVD, thereby manufacturing the second prototype device experimentally. FIG. 9 is a drawing showing the result of measurement to measure the concentration distribution of Zn atoms as the p-type dopant in the second prototype device by SIMS.

In FIG. 9 the measurement result is illustrated in the form similar to that in FIG. 7 described above. As shown in FIG. 9, the measured doping concentrations of Zn in the respective layers do not agree with the as-designed doping concentrations of Zn (in the fifth column in FIG. 8) shown in FIG. 8. Particularly, noting the part of the p-type InP layer of the fourth layer encircled by a dotted line in FIG. 9, its Zn atom concentration is not more than 1×10¹⁵ cm⁻³ which is the measurement limit of SIMS.

It is understood from this result that the result shown in FIG. 9, different from the result of FIG. 7, indicates that the Zn concentration in the p-type InP layer of the fourth layer in the second prototype device is not 2×10¹⁶ cm⁻³, which was the predetermined atomic concentration as designed. It can also be seen from the result in FIG. 9 that Zn atoms are segregated at the interface to the n-type InP layer of the third layer in the second prototype device. The same result was confirmed through repetitive operations of the epitaxial growth and analysis. The same result was also obtained with devices fabricated by epitaxial growth under different conditions, e.g., different temperatures or gas flow rates, with another MOCVD system.

These results infer the following: “in the semiconductor device with Zn as a p-type dopant and with the heterostructure wherein the p-type binary semiconductor layer doped with Zn in the low concentration of not more than 1×10¹⁸ cm⁻³ is deposited on the p-type ternary/quaternary semiconductor layer doped with Zn in the low concentration of not more than 1×10¹⁸ cm⁻³, or in the case of the first prototype device, the predetermined Zn doping concentration as designed is achieved as proved by analysis of the concentration distribution after deposition. However, when the ternary/quaternary semiconductor layer is deposited on the binary semiconductor layer contrary to the above, or in the case of the second prototype device, the abnormal diffusion of Zn occurs in the binary semiconductor layer, irrespective of the growth systems and growth conditions, as proved by analysis of concentration distribution after deposition, and the predetermined Zn doping concentration as designed is not achieved in the binary semiconductor layer.”

In the case of the second prototype device, even if the Zn doping concentration in the p-type InP layer of the fourth layer was designed to be higher, e.g., 1×10¹⁷ cm⁻³, the predetermined atomic concentration as designed was not achieved in the p-type InP layer of the fourth layer and the measured concentration was not more than the measurement limit of SIMS. This result infers that “the abnormal diffusion of Zn occurs independent of the doping concentration.”

With occurrence of such abnormal diffusion of the p-type dopant, there will arise the problem that it is impossible to accurately control the carrier concentration in the semiconductor layer suffering the abnormal diffusion and, as a result, an electronic device or an optical device fabricated with the semiconductor layer, for example, as a photosensitive layer of a semiconductor light receiving device or as a light emitting layer of a semiconductor light emitting device fails to hold as-expected characteristics.

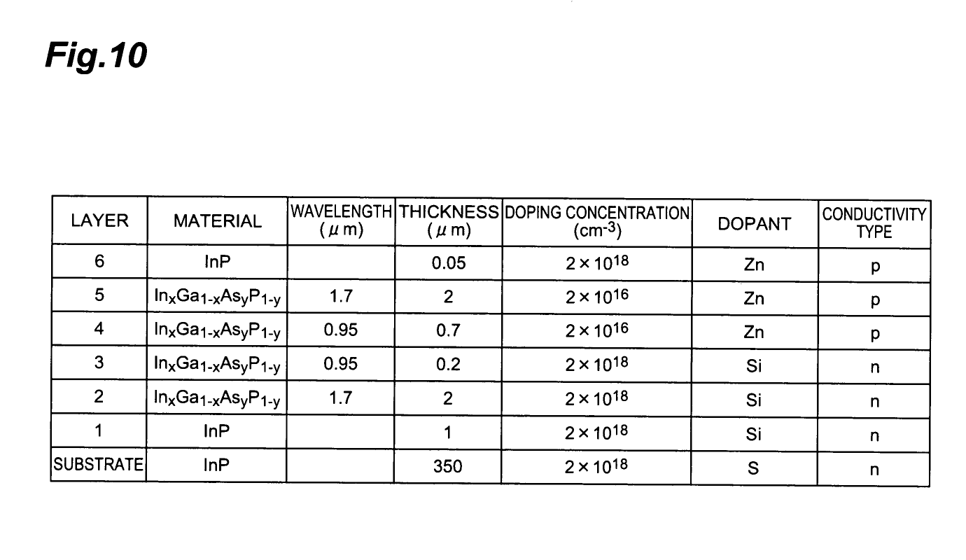

Subsequently, the inventor experimentally manufactured still another semiconductor device (which will also be referred to as a “third prototype device”) by MOCVD in the same manner as in the case of the first prototype device and the second prototype device. FIG. 10 is a drawing showing a table of the designed particulars of the materials, thicknesses, etc. of the respective layers, for manufacturing the third prototype device experimentally. As shown in FIG. 10, the third prototype device manufactured experimentally is different in the third layer and the fourth layer from the second prototype device shown in FIG. 8.

Namely, the third layer of the n-type InGaAsP semiconductor layer is so designed that its wavelength is 0.95 μm, that its thickness is 0.2 μm, and that the doping concentration of Si is 2×10¹⁸ cm⁻³. The fourth layer of the p-type InGaAsP semiconductor layer is so designed that its wavelength is 0.95 μm, that its thickness is 0.7 μm, and that the doping concentration of Zn is 2×10¹⁶ cm⁻³. In this manner, the third prototype device is so designed that, instead of the p-type InP layer of the fourth layer which suffered the abnormal diffusion of Zn in the second prototype device, the fourth layer is the p-type InGaAsP layer having the energy gap close to that of the p-type InP layer and larger than that of the p-type InGaAsP semiconductor layer of the fifth layer.

With this third prototype device, the concentration distribution of Zn atoms as the p-type dopant was measured by SIMS, and the result thereof was similar to FIG. 9 described above. Namely, the measured doping concentrations of Zn in the respective layers disagreed with the as-designed Zn doping concentrations in FIG. 10 (in the fifth column in FIG. 10). The same result was confirmed through repetitive operations of the epitaxial growth and analysis. The same result was also obtained with devices fabricated by epitaxial growth under different conditions, e.g., different temperatures or gas flow rates with another MOCVD system.

It is believed from the results of the experiments with the first prototype device, the second prototype device, and the third prototype device as described above that “when the semiconductor device is so constructed that it has the first III-V compound semiconductor layer and the second III-V compound semiconductor layer making the heterojunction and that the energy gap of the second III-V compound semiconductor layer is smaller than that of the first III-V compound semiconductor layer, the abnormal diffusion of the p-type impurity does not occur from the growth system or the growth conditions, but does occur from the essential problems arising from the semiconductor heterostructure and the type of the p-type impurity.” There were no prior art documents or patent documents pointing out the problem of such abnormal diffusion, and the reason for it has not been elucidated.

The present invention has been accomplished based on the new findings as described above and in order to prevent the abnormal, diffusion of the p-type impurity in the low concentration region in the case where the ternary/quaternary semiconductor layer is deposited on the binary semiconductor layer.

The present invention was described above with the preferred embodiments thereof, and it is needless to mention that the present invention is not limited to the above-described embodiments. For example, the above described that the surface emitting diode 200 a part of the substrate of which was removed, for example, in order to improve the coupling efficiency with optical fiber, or the back-illuminated photodiode 300 was an example of the optical device including the semiconductor device of the present invention, but, without having to be limited to this example, the semiconductor device of the present invention can also be applied, for example, to so-called edge emitting type LEDs emitting light from an end face.

What is claimed is:

1. A semiconductor device comprising a first III-V compound semiconductor layer and a second III-V compound semiconductor layer doped with a p-type impurity and joined to each other to make a heterojunction;
wherein the first III-V compound semiconductor layer or the second III-V compound semiconductor layer functions as a photosensitive layer or as a light emitting layer;
wherein an energy gap of the second III-V compound semiconductor layer is smaller than an energy gap of the first III-V compound semiconductor layer; and
wherein beryllium (Be) or carbon (C) is used as the p-type dopant in the first III-V compound semiconductor layer and the second III-V compound semiconductor layer.

2. The semiconductor device according to claim 1, wherein the second III-V compound semiconductor layer is deposited on the first III-V compound semiconductor layer.

3. The semiconductor device according to claim 1, wherein the first III-V compound semiconductor layer and the second III-V compound semiconductor layer contain at least one from each group of (In, Ga, Al) and (As, P, N).

4. The semiconductor device according to claim 1, wherein the first III-V compound semiconductor layer is a III-V compound semiconductor layer of a binary compound semiconductor, and
wherein the second III-V compound semiconductor layer is a III-V compound semiconductor layer of a ternary compound semiconductor or a quaternary compound semiconductor.

5. The semiconductor device according to claim 1, wherein the first III-V compound semiconductor layer and the second III-V compound semiconductor layer are grown by molecular beam epitaxy.

6. The semiconductor device according to claim 1, wherein the first III-V compound semiconductor layer and the second III-V compound semiconductor layer are doped with the p-type impurity in a low concentration of not more than 1×10¹⁸ cm⁻³.
